(19) United States
(12) Patent Application Publication
(10) Pub. No.: US 2017/0201077 A1
(43) Pub. Date: Jul. 13, 2017

(54) CONTAINERIZED MICROGRID SYSTEM AND METHODS OF USE AND DISTRIBUTION

(71) Applicant: NRG Energy, Inc., Houston, TX (US)

(72) Inventors: Eric Hafner, Gilbert, AZ (US); Christopher Yanek, Scottsdale, AZ (US); Obrie Hostetter, San Francisco, CA (US); Chad Seeber, Scottsdale, AZ (US); Teddy Wright, Phoenix, AZ (US); Michael Perez, Scottsdale, AZ (US); Nazar Al-Khayat, Scottsdale, AZ (US); Travis Sarver, Queen Creek, AZ (US); Vitali Buturlia, Mesa, AZ (US); Seth DeValve, Manchester, CT (US)

(21) Appl. No.: 14/996,052

(22) Filed: Jan. 14, 2016

Related U.S. Application Data
(60) Provisional application No. 62/276,720, filed on Jan. 8, 2016.

(51) Int. Cl. H02B 7/06; H05K 7/14; H04W 84/12; G08B 21/18

(52) U.S. Cl. CPC H02B 7/06; G08B 21/18; H05K 7/14; H04W 84/12

(57) ABSTRACT

A containerized microgrid comprising a sturdy weatherproof housing configured for easy shipping and transport, an inverter for managing renewable and non-renewable energy sources, a battery cabinet with batteries and battery management system, a solar panel storage rack with solar panels and solar panel combiner box, a communication system with satellite and terrestrial radio communications systems, a generator, a security system to protect the containerized microgrid and an optional water purification system.

### CROSS REFERENCE

This application claims the benefit of U.S. Provisional Application No. 62/276,720, filed Jan. 8, 2016, which application is incorporated herein by reference.

### BACKGROUND OF THE INVENTION

Growing ubiquity of electronic devices, internet connectivity, and an increasingly globalized workforce are resulting in corresponding expansion in the energy needs of society; both in location and power. For continued growth and to sustain the expanding needs of both developed and less developed communities worldwide, it is increasingly important that modular, self-contained energy generation and storage systems be developed. There is a need for easy to use systems that can be quickly and efficiently delivered, setup and scaled to meet growing energy needs at developing and remote locations around the world.

### SUMMARY OF THE INVENTION

The present invention discloses a modular, self-contained containerized microgrid system. The system may comprise a housing equipped with solar, battery and traditional generator energy sources and the components necessary to use these energy sources to support a variety of energy loads. The system is modular, easily shipped as a single unit or part of a multi-unit array and the units can be scaled with growing energy needs. The system may be further equipped with water purification, storage, satellite communication and surveillance systems. The system may be configured for easy distribution, and could be rented or sold and shipped in synchronization with the energy needs transmitted by the system to the user or an external operator.

These and other embodiments are described in further detail in the following description related to the appended drawing figures.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 shows an example of a containerized microgrid with components.

FIG. 2A and FIG. 2B show side views of external housing of a containerized microgrid.

FIG. 3 shows a side perspective view of containerized microgrid, from the FIG. 2A direction.

FIG. 4A, FIG. 4B, and FIG. 4C represent an inside view of containerized microgrid with human shown for perspective.

FIG. 5A, FIG. 5B-C and FIG. 5D-E depict individual solar panels with respective closed, erect and exploded views.

FIG. 6A, FIG. 6B, FIG. 6C, FIG. 6D, and FIG. 6E represent the respective battery cabinet, tray, cell, rack, and battery management system.

FIG. 7A and FIG. 7B depict the water purification system and storage tank.

FIG. 8 represents the communications system with wireless LAN system for device management.

FIG. 9 depicts an example of the surveillance and security system.

FIG. 10A, FIG. 10B, and FIG. 10C show the self-contained or multi-component system configurations.

FIG. 11 represents the inverter and Hybrid Power Control (HPC) System with exemplary loads and power sources.

FIG. 12 is a circuit diagram showing the connectivity of the solar array, the battery bank, the genset, the HPC and an example of critical and non-critical loads.

FIG. 13 is a circuit diagram showing the connectivity within components of the solar array.

FIG. 14 is a circuit diagram showing the connectivity within components of the battery bank.

FIG. 15 is a circuit diagram showing power sources for network connection and ethernet connectivity.

FIG. 16A and FIG. 16B is a schematic for a genset generator that could be used in the containerized microgrid.

FIG. 17 is a schematic for an intermodal shipping container for housing a containerized microgrid.

FIG. 18 is a schematic showing assembly joints that connect housing of the containerized microgrid.

### DETAILED DESCRIPTION OF THE INVENTION

A system for managing and bearing energy loads may be provided. The system may include one or more containerized microgrids. The term “microgrid” as used herein, refers to any grouping of electrical loads and distributed energy resources. Energy resources within a microgrid may operate in a coordinated way, as an autonomous unit or as part of a main power network. Components of the containerized microgrid may be built into a unitized and multi-functional container unit or housing. The housing may be designed to be easily transported via land, sea and air. An energy management system may permit the connection of multiple units to form a modular grid system. The storage unit may be provided as a container that may prevent exposure of the components to rough weather conditions, and may reduce the likelihood of component breakage and theft. Furthermore, the storage unit may be outfitted with other security devices including a surveillance system, and a communications system that enables wireless transmission of data and information.

The containerized microgrid system may further comprise one or more individual containerized microgrid units. A containerized microgrid system may support temporary, semi-permanent, or permanent needs of a customer. One or more of the units may be easily deployed to the customer sites, and the units may be sold or provided on a rental basis. The containerized microgrids may be provided as one or more modular container, each with optional attachments such as potable water purification systems and communication stations. The individual containerized microgrid units may be linked together allowing an energy supply to be scaled through the addition of new units, and in accordance with the needs of the customer. The containerized microgrid system may include a communications station for accepting and transmitting signals including satellite signals, a voice local area connection (VLAN), and/or a local area network (LAN) network connection as well as a WIFI access point that may provide wireless internet access to WIFI enabled devices. A containerized microgrid system may support temporary, semi-permanent, or permanent needs of a customer. One or more of the units may be easily deployed to the customer sites, and the units may be sold or provided on a rental basis. The containerized microgrids may be provided as one or more modular container, each with optional attachments such as potable water purification systems and communication stations. The individual containerized microgrid units may be linked together allowing an energy supply to be scaled through the addition of new units, and in accordance with the needs of the customer. The containerized microgrid system may include a communications station for accepting and transmitting signals including satellite signals, and a local area network (LAN) network connection as well as a WIFI access point that may provide wireless internet access to WIFI enabled devices.

A method may be provided for distributing modular containerized microgrid power sources to customers that want to supplement their main grid power or have energy needs at remote locations where access to a main grid access is not available. Information about load distribution and energy performance may also be transmitted from the containerized microgrid unit through the communications station to one or more remote locations or to a server, allowing the operational status and usage data to be tracked and monitored; these data may be used to determine if one or more new containerized microgrid systems needs to be deployed. The containerized microgrid system may be provided as part of a scalable energy source that meets the needs of a single standalone system, multiple standalone systems, or a permanent reliable energy grid that requires a supplemental energy source. The containerized microgrid system may be implemented using a single containerized microgrid unit, multiple containerized microgrid units, and/or in combination with existing energy grids. This unitized containerized microgrid system may be implemented and scaled with minimal effort by the end user.

Overview of Containerized Microgrid Components

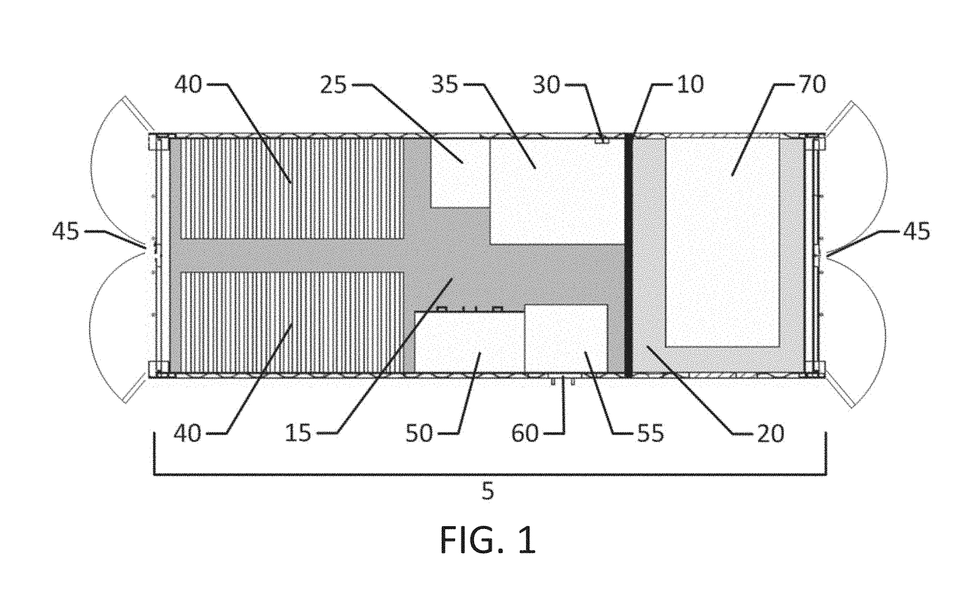

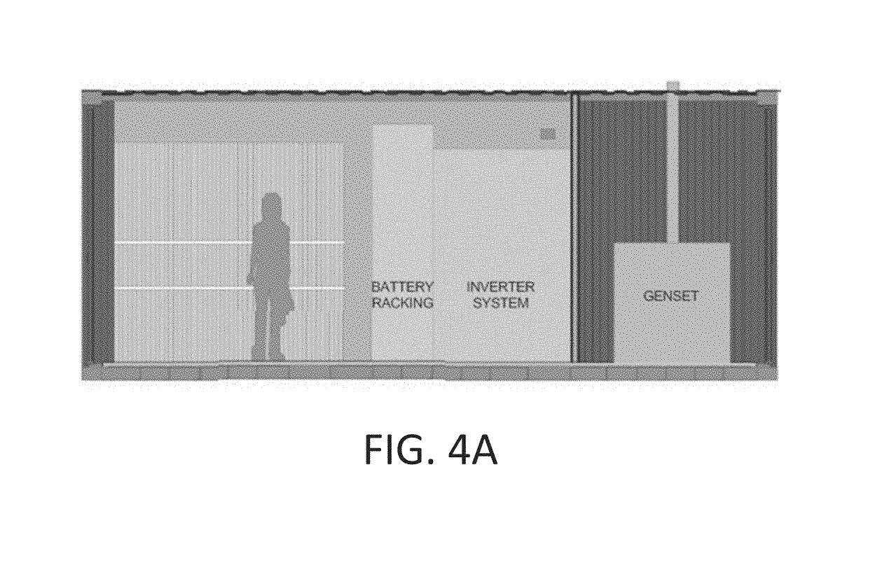

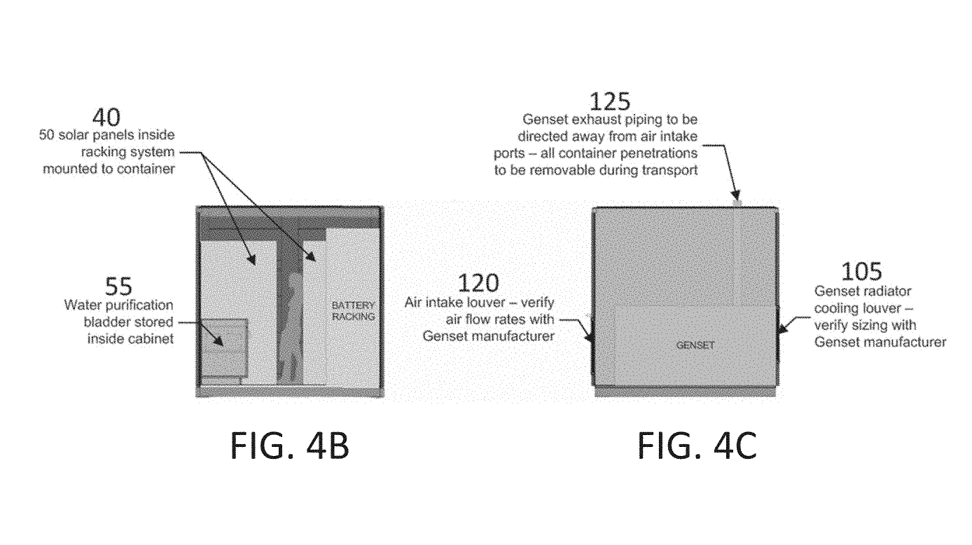

FIG. 1 depicts a non-limiting embodiment of the containerized microgrid unit. In some embodiments, as depicted in FIG. 1 and FIG. 4A, microgrid unit 5 may comprise a housing which may enclose a volume that may be separated by paneling, for example a single panel 10 that creates two compartments; a larger space referred to as the main storage unit 15, and a smaller space referred to as the genset room 20. The main storage unit 15, and the genset room 20, may be isolated from each other and accessed independently housing doors 45. The main storage room 15 may be comprised of a battery rack 25, a communications station 30, an inverter 35, a solar panel racking system mounted to both sides of the housing 40, housing doors 45, a housing main storage rack 50. The system may be further adapted with a water purification system 55 equipped with a water dispensing port 60 and interchangeable hose connections and ports that can be disconnected during transport. The genset room 20 may be isolated from the main storage compartment, and comprise a genset 70 which may, for example, comprise a diesel generator, a combination of diesel engine and electric generator, or any other machine used to generate electricity. The genset room may have a ventilation system that may comprise a genset radiator cooling louver 105, an air intake louver 120 and exhaust piping 125.

A containerized microgrid unit 5 may be contained in a housing designed to make the system secure, easy to ship, and self-contained. The housing may optionally form an intermodal shipping container. The intermodal shipping container may be compliant with International Standards Organization (ISO) standards, it may comprise an ISO number that can be tracked during shipment. Housing may be constructed of steel, aluminum, wood, or other standard durable materials. The housing components may be corrugated or welded. The housing may comprise one or more of the containerized microgrid components, such as any of the components described elsewhere herein. The components may remain within the housing during delivery and/or deployment. Alternatively, one or more components may be removed from the housing during delivery and/or upon deployment. For instance, one or more components may be outside the housing, and/or exposed to the environment when the containerized microgrid unit is in use. In some instances, one or more components may be removed from within the housing and spread on a surrounding surface around the containerized microgrid unit. The housing may be formed from a rigid material that may protect one or more of the components. The housing may include one or more openings that may be repeatedly opened and/or closed. For example, one or more doors, windows, portals, skylights, and/or hatches may be provided on the container. Doors 45 may be standard or heavy duty; they may be swing opening or roll up. Doors, windows, portals, skylights, and/or hatches may be constructed any number of materials including galvanized steel, anodized metal aluminum, and wood. Doors, windows, portals, skylights, and/or hatches may be insulted, and may comprise sliding locks, manual key locks, deadbolts, handle locks, cargo door locks, security swing arms with or without lock box, lock box to restrict lock access, security keypads, biometric locks including fingerprint reader or iris scanner, or any other locking or security mechanisms. The housing may optionally protect components within the container from environmental conditions (e.g., rain, wind, dust, heat, radiation). The housing may or may not be fluid-tight.

The housing may have any shape or dimension. For example, the housing may form a rectangular prism, a cube, a chain of rectangular prisms, orthogonal rectangular prisms, or any combination thereof. The housing may have a length, width, height, diagonal, diameter, or any other dimension that may be less than or equal to 10′, 20′, 40′ or 45′. For some embodiments, particular those comprising an intermodal shipping container the container may have a width of 8′, a height of 8′ 6″ or 9′ 6″ and length of less than or equal to 10′, of less than or equal to 20′, less than or equal to 40′, greater than or equal to 40′, greater than or equal to 45′.

In some embodiments, the housing may be divided into one or more compartments of varying sizes. The separations 10 may be constructed of any material including structural insulated paneling, fiberglass reinforced plastic (FRP) paneling, sheet metal, plywood, cement, magnesium oxide board, oriented strand board, plaster, or any combination thereof. In further embodiments, the paneling may be mounted to a metal stud wall with sound attenuation batt for limiting sound transmission between the adjacent spaces. The separations may or may not include a door or other opening that may enable an individual to traverse compartments. In some embodiments, different types of components may be stored within different compartments of the unit. Any number of compartments or rooms may be formed within the unit. For instance, one or more, two or more, three or more, four or more, five or more, or six or more compartments may be provided. The compartments/rooms may have similar dimensions to one another or different dimensions from one another. In some instances, different compartments and/or rooms may have different functions, such as storage, energy generation, battery storage, solar panel storage, inverter storage, energy storage, communications, surveillance, and/or water generation/storage.

In further embodiments, the housing may be outfitted with heating, ventilation and air conditioning (HVAC) options. HVAC options may comprise window air conditioners, commercial through-wall HVAC, ventilation-air ducts, rooftop turbine vents 125, fixed louver vents 105/120, exhaust fans 115, or any combination thereof. HVAC options may come pre-installed, or as one or more separate units for installation after delivery. Window air conditioners and through-wall HVAC systems may have cooling, or cooling and heating capabilities. Through-wall HVAC systems may range in size from 1.5 to 5 tons. In some embodiments ventilation-air ducts may be exposed or hidden in a ceiling of the container. Rooftop turbine vents may be powered with energy or passive without power. Louver vents may be standard 12″ to 36″ size; they may be installed independently or in conjunction with exhaust fans, and may further comprise bird screens. Exhaust fans may be standard size ranging from 10″ to 36″ with variable or fixed speed control, and may further comprise guards, gravity shutters, or any combination thereof.

In further embodiments, the container may be outfitted with electrical lighting, outlets 110, electrical receptors/plugs, or any combination thereof. The wiring may be installed behind walls or run along the surface of the housing within a conduit. Electrical receptacles may comprise standard 110V with one or more outlets, including the standard two or four outlets. Electrical receptacles may be exposed on the surface of paneling, or flush mounted. They may be mounted anywhere in the housing, facing externally or internally, and may further comprise waterproof covers. Lighting may be configured inside the housing to illuminate internal compartments, or configured outside the housing. Overhead lighting may be used, particularly indoors. Outdoor lighting may comprise porch lighting to illuminate a door or window, flood lights to illuminate the perimeter of the housing, security lights with motion sensors, and location beacons, signaling beacons or distress indicators mounted to the top or sided of the housing. Light bulbs may comprise incandescent bulbs including standard incandescent bulbs and tungsten-halogen bulbs, High-Intensity Discharge (HID) bulbs, fluorescent bulbs including compact fluorescent bulbs (CFLs), light emitting diodes (LEDs) or any other bulbs light source. The bulbs may be reflectorized, made of storm resistant coatings or glass, temperature resistant, weather proof, or modified in any other way to withstand environmental conditions. Lighting may be connected to one or more direct or indirect switches including a standard light switch, non-standard or waterproofed switches, timers, trip sensors, motion sensors, or any other mechanism for controlling power to a light source. Multiple switches or controllers may be installed for control of lights from different locations inside or outside the housing.

The unit 5 may have walls, panels 10, doors 45, windows or other components of the housing or panels within the housing may be insulated, and optionally finished with additional paneling. Insulation may comprise fiberglass insulation FRP plywood paneling, fiberglass insulation with Hardie paneling, rigid polystyrene foam paneling, closed cell spray foam, or any combination thereof. Insulation may be wood framed, wherein the insulation is rolled behind plywood, or Hardie paneling. In further embodiments the insulation may be topped with an FRP overlay, Hardie paneling or plywood. In some embodiments rigid polystyrene foam paneling may be used, paneling may be secured with steel studs or to flat bar. Other embodiments may comprise closed cell spray foam that directly covers the surface of the housing walls. The housing floor may comprise overlays, coverings or coatings including marine plywood, steel overlay, vinyl flooring, Rhino Liner™ including polyurethane or polyurea, or even no floor covering at all.

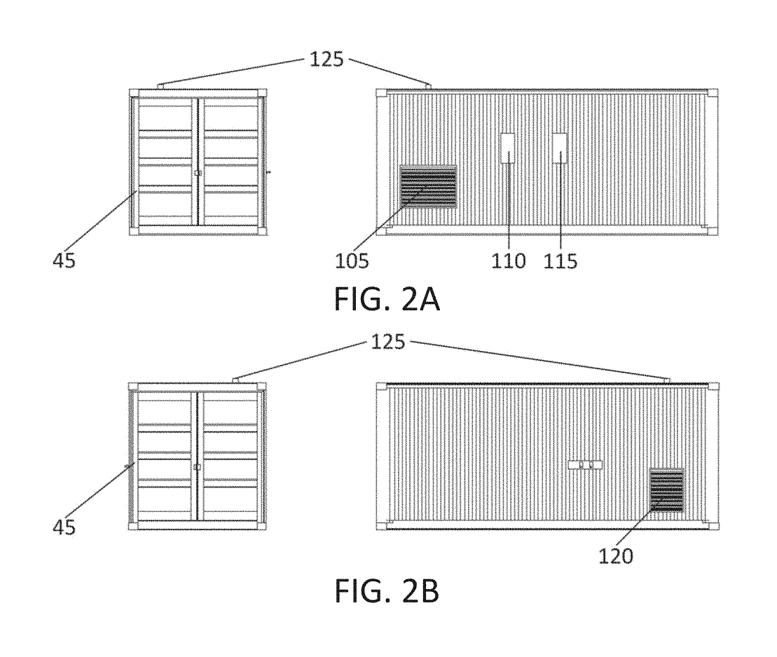

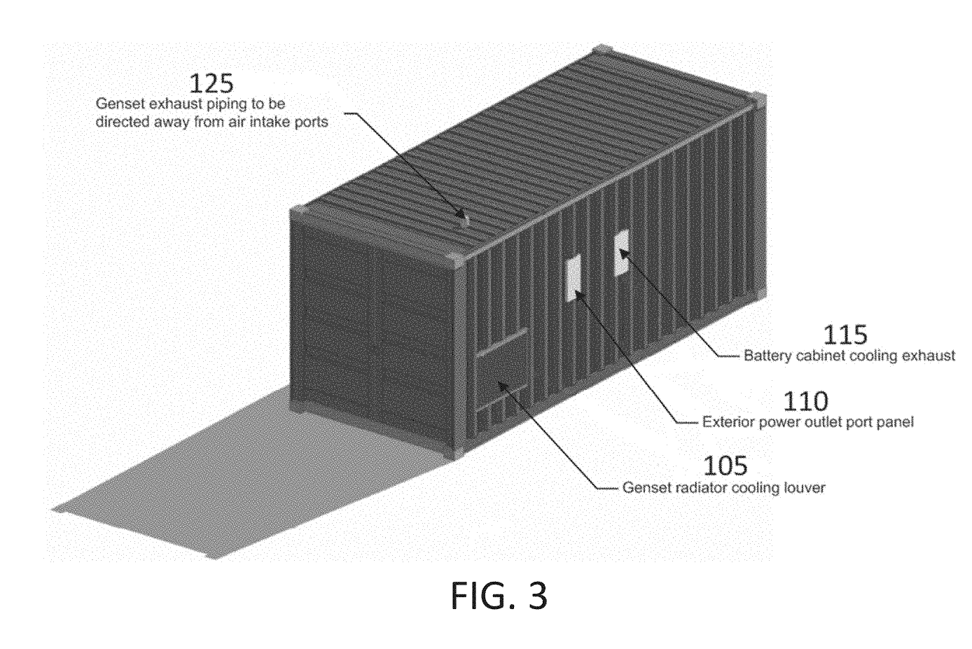

The housing may be modified to support operation of the enclosed components. In some non-limiting embodiments, as shown in FIG. 2A-C, FIG. 3 and FIG. 4C, several mechanisms may be built into the walls of the housing for maintain appropriate operating temperatures for components of the containerized microgrid, or for providing power outlet access. On one side of the unit (top FIG. 1, FIG. 2A, FIG. 3, FIG. 4C) the housing may be equipped with a battery cabinet cooling exhaust 115 to keep the battery cabinet at appropriate operating temperature, and an exterior power outlet port panel 110 for accessing the power source without the need to run wires through the doors of the housing. To maintain reasonable conditions in the genset room 20, the housing may be further equipped with a genset radiator cooling louver 105 on one side of the compartment (top FIG. 1, FIG. 2A, FIG. 3, FIG. 4C), and an air intake louver 120 on the other side of the compartment (FIG. 1 bottom, FIG. 2B) with a genset exhaust piping directed away from air intake ports 125 for exhausting air out of the top of the housing (FIG. 2A-B, FIG. 3, FIG. 4C). Access to the units may occur through the FRP insulated housing doors 45. A pair of housing doors may be installed on each side of the unit, with one set allowing access to main storage and a second pair allowing access to the genset unit, permitting isolation of components in the main storage compartment and the genset room.

A user may enter individual compartments of the containerized microgrid through one or more doors, windows, or portals. In one embodiment, depicted in FIG. 4A-4B, the housing may be configured such that a user may enter the main storage compartment of the containerized microgrid unit to access components of the system. In some embodiments entering the main storage compartment may provide access to microgrid components comprising the solar panel storage racking system 40 and solar panels stored in the racking system, the battery rack 25 and batteries connected in the battery rack, the inverter system 35 and hybrid power conditioning system as well as any dials or readouts on the inverter system, the water purification station 55 which may comprise a bladder stored inside a storage cabinet, and the communications station. Occupants of the housing may also be able to access hardline connections to the communications system, outlets for power access, and light switches to turn on inside or outside lighting. In some embodiments a user or other individual may also enter the genset room through an alternate set of doors 45 to gain access to other components including the genset 70, the genset radiator cooling louver 105, the air intake louver 120 and genset piping 125.

A microgrid unit may be capable of generating energy that may be provided to a local region. The microgrid unit may include a fuel generator and/or one or more renewable energy sources. The microgrid unit may be a hybrid energy generator that relies on both the fuel generator and the one or more renewable energy sources. An energy storage system may operate in conjunction with the fuel generator and/or the one or more renewable energy sources.

The fuel generator may operate to generate electricity by consuming fuel. Examples of fuels may include liquid, solid or gas fuels. Liquid fuels may include petroleum, diesel, gasoline, kerosene, LPG, coal tar, naptha and ethanol. Solid fuels may include wool, coal, peat, dung, coke and charcoal. Gaseous fuels may include natural gas, hydrogen, propane, coal gas, water gas, blast furnace gas, coke oven gas, and compressed natural gas. The generator may include dynamos, alternators, rotars, stators, turbines, armatures, field generators. The generators may produce alternating current, direct current or both alternating and direct current. Direct current generators may include homopolar generators or magnetohydrodynamic generators (MDH generators). Alternating current generators may include induction generators, linear electric generators or variable speed constant frequency generators. The electricity generated by the generator may be delivered directly to a load and/or may be stored.

The renewable energy sources may include solar energy and/or wind energy. Examples of a solar panel system are described in greater detail elsewhere herein. The renewable energy sources may generate electricity. The electricity may be directly delivered to a load and/or may be stored. An energy storage system may include one or more batteries or other energy systems. Examples of energy storage systems are provided in greater detail elsewhere herein. The energy storage system may delivery electricity to a load.

Solar Panel Rack, Solar Panels and Solar Array

One or more solar panels may come stored in a solar panel racking system 40. The solar panel racking system may be stored within a microgrid housing. The racking system may be stored within the microgrid housing during transport and may optionally be removed from the housing after the microgrid unit has reached its destination for deployment. In some embodiments the racking system may comprise one, greater than one, greater than 2, greater than 4, greater than 10, greater than 25, greater than 50, greater than 100, or greater than 1000 solar panels. The racking system may permit storage of solar panels within a relatively compact manner while being transported. For instance, the racking system may permit a storage density of greater than or equal to about 1, 2, 3, 5, 10, 15, 20, 30, 40, 50, 75, 100, 150, 200, 500, 1000, or 2000 solar panels per square foot. The solar panels may be stacked on top of one another, or stacked next to one another. In some instances, multiple stacks, rows, or regions of solar panels may be stored within the container. The solar panel storage racking system may be mounted using stainless steel rivets, through soldered corners and edges, interlocking joints, or any other method of combining individual support units to form a structured racking system. The racking system may be built into the container or attached to the container. In some instances, the racking system may not be removable from the container with aid of one or more tools. Optionally, the racking system may be permanently attached to or integrated into the container. In some embodiments the solar panels may be accessible through the main storage compartment. The racking system may optionally allow the solar panels to contact one another. Alternatively, they may separate the solar panels and prevent them from touching one another, or separate groupings of solar panels. The solar panel storage racking system may protect the solar panels and prevent damage to the solar panels during transport.

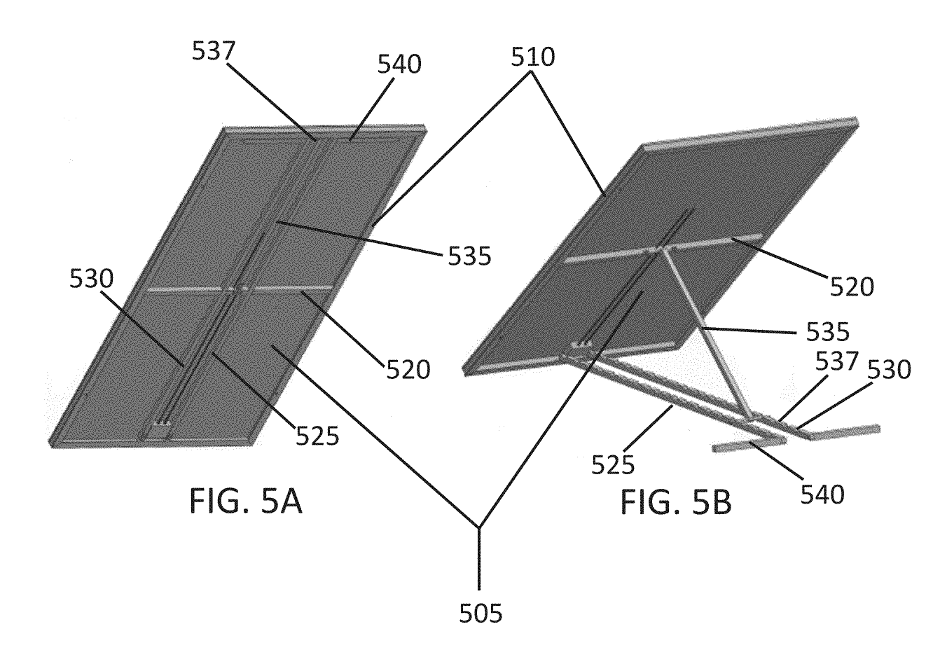

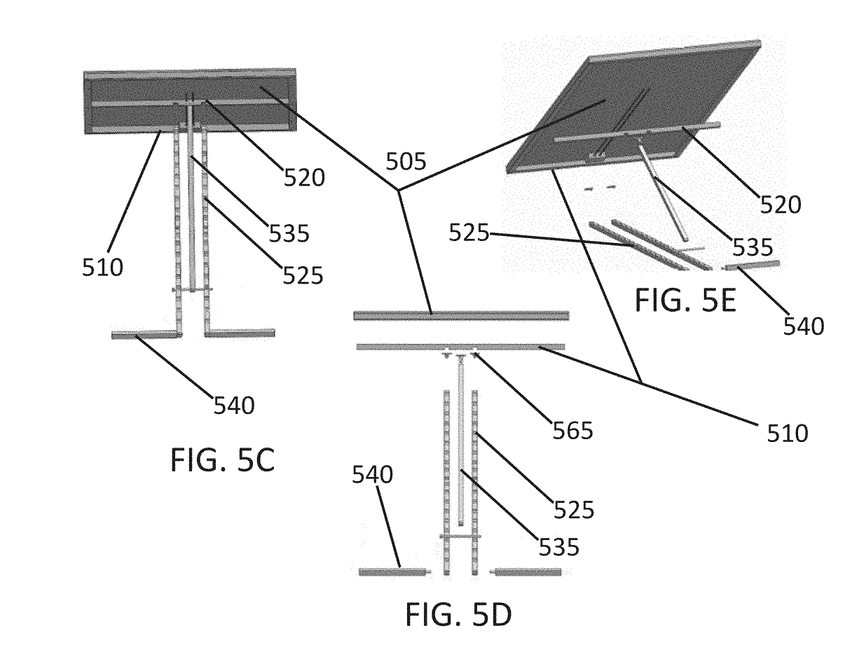

In some embodiments the solar panels, as shown in FIG. 5A-5D, may comprise photovoltaic (PV) panels 505. During setup the user may remove the panels from the racking system and set them up as part of an array outside of the containerized microgrid housing. The PV panels may be connected into a PV system, comprising an array of PV panels. The total size of the PV system may comprise greater than or equal to: 50 kW, 150 kW, 500 kW, 1 MW, 5 MW, 10 MW, 30 MW, 50 kW, 100 MW, or 150 MW. Cell panels may be monocrystalline, thin-film, or polycrystalline. There may be a total of 100 polycrystalline 315w, 72 cell panels, or any other number of solar panels with variable wattage and cell panel numbers. The panels may be grouped. Groups of panels may be wired in series, in parallel, or any combination thereof. Panels in groups may be wired in series, in parallel, or any combination thereof. For instance, the panels may be wired in series of 10×10. Panels may be deployed in any physical arrangement. In some instances, groups of panels may be provided within the same region. The panels may be distributed within an environment where the container is deployed. The panels may rest on the ground. The panels may or may not be affixed to the ground. The panels may be flat mounted, or pivoted with adjustable pivots. Pivot may adjust to a fixed angle or any range of angles, including at 45 degrees and cover a range or fixed surface area. For instance, the panels may be mounted flat and spread out over an area cover greater than or equal to: 1,014 sq. ft., 2,847 sq. ft., 4,992 sq. ft., 9,828 sq., or 14,586 sq. ft. The panels may be mounted at an angle, with a variety of coverage areas. For example, panels may be mounted at a 45 degree angle the panels may spread out over an area greater than or equal to 1,248 sq. ft., 3,900 sq. ft., 7,059 sq. ft., 13,923 sq. ft., or 20,787 sq. ft. An anchoring system may or may not be used to affix panels to the ground. The panels may be configured to withstand winds of up to at least 10, 15, 20, 30, 40, 50, 60, 80, 100, 120, 150, 180, or 200 mph. The panels may be distributed freely in any manner. In some embodiments, a solar panel arrangement may be selected based on the terrain and/or other environmental factors such as shading, sun positions, wind patterns, or any other conditions. The positions of the solar panels relative to one another or the containers may be adjusted.

The solar panels may be electrically connected to the container. The solar panels may be electrically connected to the container with aid of one or more wired connections. The solar panels may communicate with the container. Optionally, one-way communications may be provided from the solar panels to the container or from the container to the solar panels. Alternatively, two-way communications may be provided between the solar panels and the container. Information from the solar panels to the container may include information about energy production, operational states, efficiency, alarm or malfunction conditions, or any other information. Information from a container to the solar panels may include information such as commands to adjust an operational state of the panel (e.g., turn on, off, adjust energy collection modes, etc.), or adjust a position of the panel.

The panels may be ground mounted with framing sections, 510. The solar panels may all be of the same size or have varying sizes. The solar panels may have the same shape or varying shapes including squares and rectangles. The length of the solar panels may be greater than or equal to: 500 millimeters, 1000 millimeters, 1500 millimeters, 1956 millimeters or 2500 millimeters. The width of the panel may be greater than or equal to 500 mm, 992 millimeters, or 1500 millimeters. Each panel may weigh less than or equal to: 10 kgs, 15 kgs, 24 kgs, or 30 kgs prior to framing. The framing sections may have multiple sizes and shapes. For instance, the framing may less than or equal to: 0.5″, 1″, 1.5″ or 2″ square with varying lengths. The framing may be constructed from reinforced polyurethane foam, aluminum, or any other materials that are light and capable of supporting the system.

A solar panel mount 515 may be used to support the panel. The solar panel mount may comprise a hinged lever arm 520. The mount may also include one, two, or more base arms 525 extending the length of the panel. The base arms may include one or more grooves 530. The grooves may be used to hold the position of the intermediate support arm 535. The intermediate support arm may have one or more cross-bar 537 that may fit into the grooves. The base arms may optionally have one or more support feet 540. The base arms (optionally, including the support feet) may rest upon a surface upon which the panel is deployed. The base arms may be affixed to the surface upon which the panel is deployed. An object securing the base arms to the surface may optionally penetrate the surface.

The panels may be locked in discrete positions ranging between 0 and 90 degrees. The grooves may be spaced apart on the base arms to provide a plurality of possible positions for the panels. In some instances, the degree of control of panel positioning may be on the order of less than or equal to about 0.5 degrees, 1 degree, 3 degrees, 5 degrees, 10 degrees, 15 degrees, 20 degrees, or 30 degrees. In some instances, the weight of the panel may be sufficient to support the panel in its selected position. Alternatively, additional locking mechanisms may be employed to keep the panel in its selected position. The grooved base arms are provided by way of example only, and other mechanisms may be provided for allowing the panels to be propped up at different positions. In some instances, the panels may be manually propped up and/or have their angle adjusted. The positions of the panels may be changed depending on the season, weather, time of day, sun position, or any other factor. The positions of the panels may be manually changed. In alternative embodiments, the positions of the panels may be automatically controlled with aid of one or more actuators (e.g., motors). The actuators may receive instructions from a panel controller regarding the positions of the panels. The panel controller may be provided at the container unit or at a remote location. The panel controller may include one or more memory storage units comprising non-transitory computer readable media including code, logic, or instructions for performing one or more steps described herein, and/or one or more processors to execute non-transitory computer readable media.

The mount may be fully collapsible within the thickness of the panel for increased storage capacity. For instance, the base arms may pivot about an axis to fold completely into the panel thickness or fold out to support the position of the panel. The intermediate arm may pivot about an axis with aid of the hinged lever arm to fold completely into the panel thickness or fold out to support the position of the panel. The axes may be parallel to one another. When the mount is in its collapsed state, the thickness of the panel, including the mount, may be no more than 20 mm, 40 mm, 60 mm or 100 mm.

Battery Rack, Batteries, and Battery Bank, Battery Management System

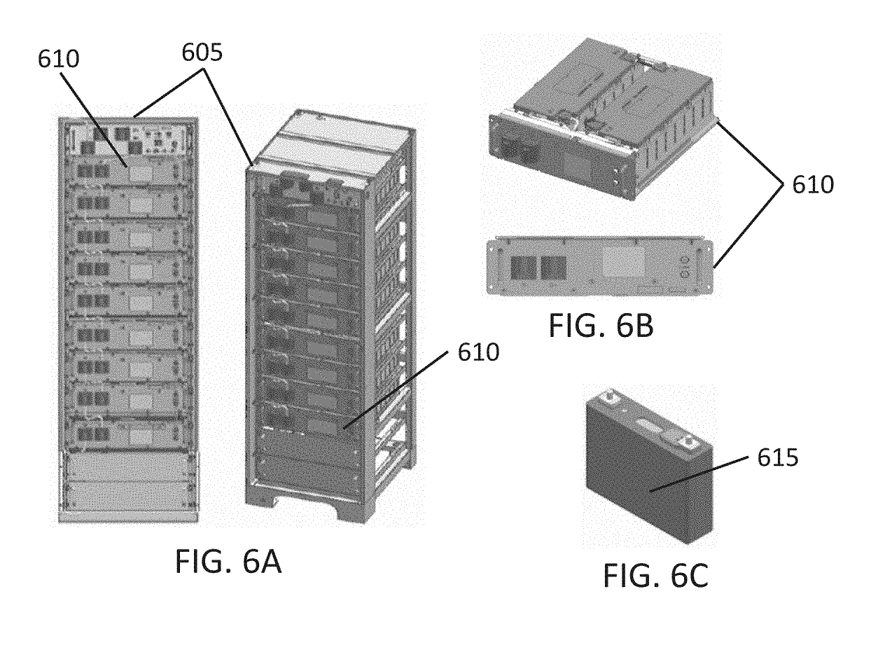

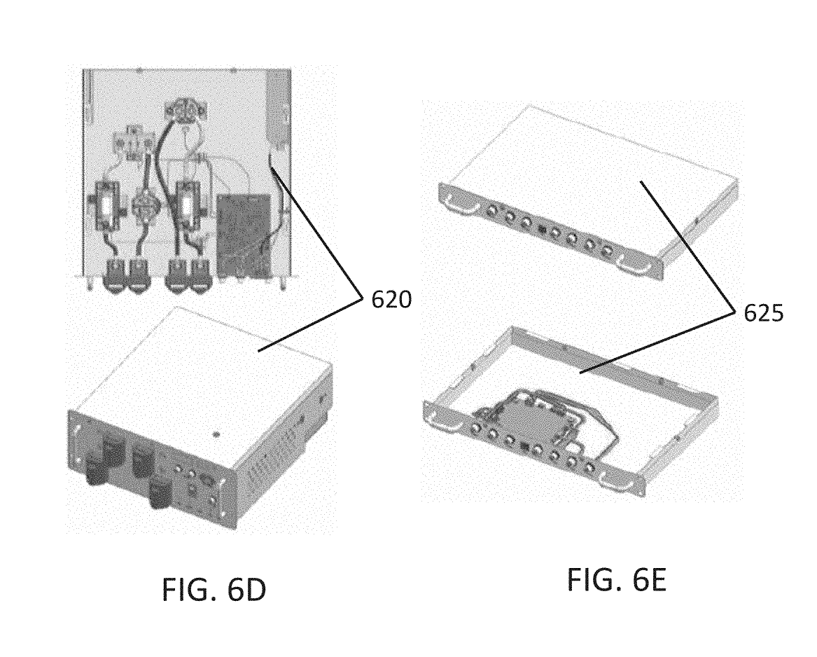

The batteries may come stored in a battery racking system 25, 605. In some embodiments the battery racking system may be configured to store one or more battery trays in one or more vertical stacks, horizontal arrangements, or any combination thereof (FIG. 6A, 605). For example, multiple trays (FIG. 6B, 610) may be stacked vertically within the battery rack to form a system with one internal switch gear (FIG. 6A, 605). Each tray may contain a tray battery management system (tray BMS) and multiple battery cells (FIG. 6C, 615), for example trays may contain greater than or equal to 8 cells, 16 cells, or 24 cells. The battery racks may include one or more battery trays which may comprise one or more battery cells therein. The battery cells, trays or racks may be connected in series, in parallel, or any combination thereof. One or more batteries within the battery packs may be connected in series, in parallel, or any combination thereof. The trays may be built into racks and equipped with rack battery management system (BMS) (FIG. 6D, 620). In some embodiments trays within a rack may share a BMS system. In further embodiments the BMS system may connect trays into a rack and connect one or more racks with other racks. In further embodiments, one or more rack BMS systems may control communication between racks or between racks and trays, and one or more rack BMS systems may connect to a system BMS which manages communication within the racks. The system BMS may also connect the rack and tray BMS array to a processor. Any type of battery may be employed including secondary cell and primary cell batteries. Examples of secondary cell batteries that may be used include lithium ion, nickel metal hydride, nickel cadmium, flow batteries, lead-acid batteries, lithium-air batteries, nickel-hydrogen batteries, and polymer-based batteries. In some embodiments the batteries may be 31.9 kWh lithium ion comprised of 9 trays of 16 CAN type LIB cells (FIG. 6C) per tray, connected by racks (FIG. 6D) in series with plus 1 integrated switch gear assembly. The battery system may comprise a single rack battery management system (FIG. 6E) and switch gear, for protecting and monitoring the batteries, and the entire system may be installed in together in 27″×20″×70″ rack. The rack may be mounted directly to the intermodal shipping housing using stainless steel rivets, through soldered corners and edges, interlocking joints, or any other method of combining individual support units to form a structured racking system. The racking system may be built into the container or attached to the container. In some instances, the racking system may not be removable from the container with aid of one or more tools. Optionally, the racking system may be permanently attached to or integrated into the container.

Potable Water Purification and Storage System

The containerized microgrid may be equipped with a potable water purification and storage system. The water purification may be a point-of-use water treatment system. It may be self-contained, mounted or comprise hand carried or removable units. The water purification system may be configured to remove water from any untreated or partially treated water sources, (e.g. rivers, lakes, groundwater etc.) The water treatment system may use one or more methods for treating the water. Methods for treatment may include ultraviolet purification, application of heat (i.e. boiling), activated carbon absorption, distillation, filtration, chemical disinfection (chlorine, iodine, ozone, etc.) and flocculation. In some embodiments filtration may comprise a combination of filters including filters to remove particulate matter, bacteria, and protozoa. Additional embodiments may use further treatment steps for example ultraviolet light treatment step to kill viruses. Reverse osmosis filtration may also be used. Water treatment through a reverse osmosis filter may be powered through mechanical, electrical or both mechanical and electrical methods. Mechanical methods may rely on pumps including hand or foot pumps. Electrical methods may rely on energy from the invertor, the generator or other power sources within the microgrid unit. The water purification and storage system may be stored in a cabinet that may be accessed from within the main storage compartment of the containerized microgrid. It may comprise interchangeable and removable hoses and attachments for use with a variety of external devices and for easy removal during transport. Potable water may be filtered on command or it may be filtered and stored in a tank. The storage tank may comprise multiple shapes, sizes and have any material composition. It may have a compacted storage size that differs from an expanded filled size. The storage unit may be a bladder, a tank or other storage system. It may be compressible, or have a fixed size. One or more components of the water storage unit may be removable for use elsewhere.

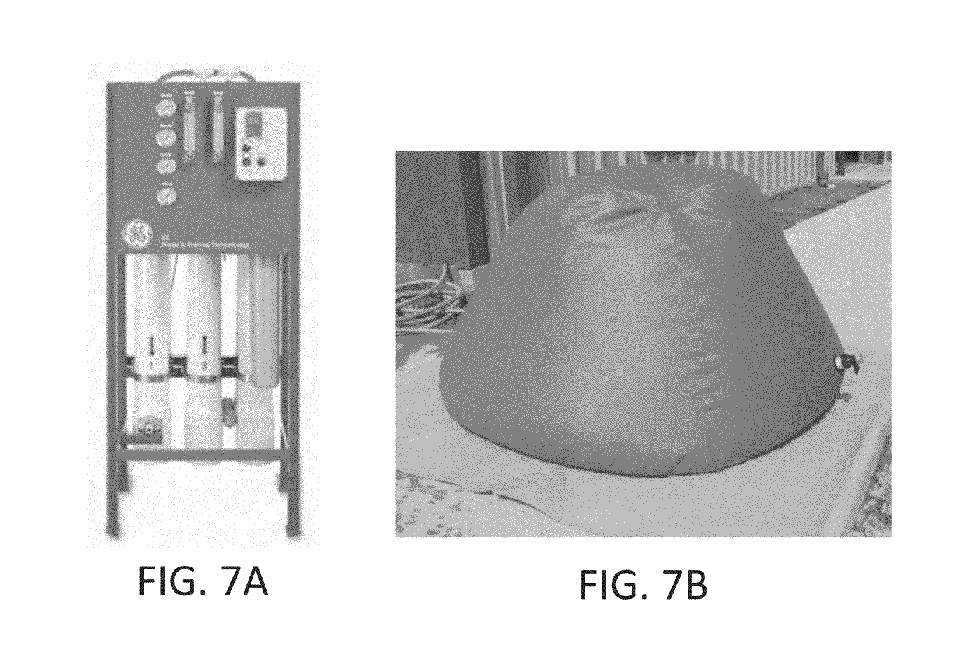

In some embodiments the potable water purification and storage system may comprise a reverse osmosis system (FIG. 7A) and a bladder storage tank (FIG. 7B). In further embodiments the reverse osmosis system may be a high brackish 50/601 Hz reverse osmosis system. The system may have a turnover of greater than or equal to 5 gallons per minute, and it may have a 35,000 maximum turbidity. The bladder storage tank may have a grey water capacity of greater than: 1 gallon, 5 gallons, 50 gallons, 100 gallons or 500 gallons gray water capacity. The water storage tank may be comprised of a barrel with a wider base than top to prevent leaning and roll over. The dimensions may be less than or greater than 48″×24″×24″ when full and less than or greater than 12″-16″ cube when folded up. Empty, the tank may weight 20 lbs, and it may comprise a ¾″ outlet with nipple and ball valve.

Data/Connectivity and Communications System

A microgrid unit may provide a local communication system to a region. For instance, the microgrid unit may be capable of communicating with one or more remote systems. The microgrid unit may permit individuals at the unit or within proximity of the unit to communicate with one or more remote systems. The microgrid unit may permit individuals within a range of the microgrid to communicate with one another. The microgrid unit may form a local network at or near the microgrid unit. The microgrid unit may provide connectivity to a wide area network, such as the Internet or a telecommunications network. The microgrid unit may be able to connect with one or more devices, such as communications satellites, towers, routers, servers, other microgrid units, or other external devices. In some instances, the one or more devices may aid in communications with other devices (e.g., satellites may aid in communication between the microgrid unit and one or more other devices).

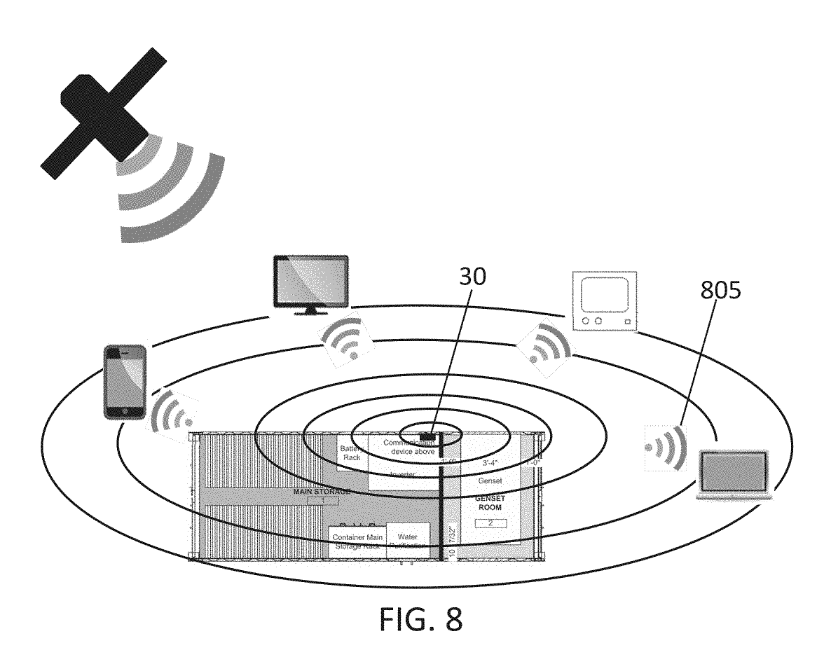

The microgrid unit may be equipped with one or more data/phone lines and or a WiFi communications portal with multiple data and phone connections. As shown in FIG. 8, some embodiments of the containerized microgrid may comprise a communication system. The communications system may be comprise a satellite communications transceiver for receiving satellite data, a terrestrial radio frequency transceiver, routers or switches, and/or one or more external devices for registering and securing communications with local devices that may be directly or wirelessly connected to the internet or other connection systems. Hard line data or voice over IP (VOIP) instillation may be made through Cat5e cable lines and terminals installed into outlets build into flush with the wall of the housing or mounted onto the side of the housing. The containerized microgrid may be further equipped with one or more external devices for registering and securing communications with local devices that may be directly or wirelessly connected to the internet or other connection systems.

The microgrid unit may create a hotspot (e.g., WiFi hotspot) within proximity of the microgrid. The hotspot may provide network (e.g., Internet access) over a wireless local area network. Broadband wireless service may be available within the hotspot. As illustrated, one or more devices within proximity of the microgrid may be capable of connecting to the hotspot to access a network. In some instances, the devices within a predetermined range of the microgrid unit may be able to access the network. In some instances, the range of the hotspot may be variable, and may optionally be dependent on environmental conditions. In some embodiments, devices may be able to access the hotspot without requiring password. Alternatively, a password or other forms of authentication may be required for the device to access the hotspot. One or more router may form the creation of a hotspot. In some instances, multiple hotspots may be created from a microgrid unit, which may have different authentication requirements and/or capabilities for each hotspot. For instance, a unit may permit an individual to access a first public network without requiring any authentication, or access a second private network which may require authentication. A first network may provide lower bandwidth than a second network, or vice versa.

The communications system of the microgrid unit may be powered by the microgrid unit. For instance, energy from a fuel generator, renewable energy source (e.g., solar panels), and/or energy storage system may be used to provide power to the communications system. In some instances, back-up power systems may be provided to power the communications system. For instance, a backup energy system may be devoted to providing power to the communications system. If a failure occurs within the regular energy production system and/or storage of the microgrid unit, the backup energy system may still permit the communication system to send a notification that the failure has been detected and/or allow individuals to make emergency communications.

Providing a hotspot may be advantageous when the microgrid unit is deployed to remote areas, where it may be otherwise difficult for individuals to connect to a network. The microgrid unit may form a nexus between the individual and communications systems. The microgrid unit may provide infrastructure that may permit an individual to access a network. An individual may be able to access a network and/or make phone calls with aid of the microgrid unit.

Security

One or more components of the containerized microgrid may be secured from removal by natural forces (e.g. rain, wind, sand storms), or from theft. In some instances, solar panels may be secured to a heavy object, the container, or anchored to the ground. The solar panels may be secured to each other. For example, the panels may be connected and secured to each other through a system of interlocking connections designed into the solar racking. The individual panels, components of panels, or panels connected through solar racking may be secured to the ground through staking, a ballasted system, or bolted connection. The various components may be protected from theft with aid of one or more locking features that may only be unlocked by an authorized individual or an individual carrying a key or other item that permits unlocking.

In some embodiments, an alarm system may be built into the solar panels or connections between the solar panels. If there is unauthorized movement or removal of the solar panels, an alarm or alert may be provided. The alarm or alert may be visible or audible at the location of the one or more solar panels, and/or may be sent to a remote location. For example, an alarm or alert may be triggered when an unauthorized individual is within a certain proximity of the solar panel. The alarm or alert may be triggered when an unauthorized individual moves the solar panel or disconnects the solar panel from other solar panels.

In some instances, attachment mechanisms may be used to prevent unauthorized removal of components from the housing. For instance, the one or more components may be permanently affixed to the housing, or an individual may only remove the component if the individual is able to unlock the component, or perform any other action, as described elsewhere herein with respect to gaining access to the housing. Examples of attachment mechanisms may include, but are not limited to adhesives, bolting, welding, soldering, locks, chains, or any other type of attachment mechanism.

The containerized microgrid may include a housing that may enclose one or more components. The housing may protect the components therein from environmental conditions. For instance, the housing may prevent rain, wind, dust, excessive heat or cold, lightning, or certain types of radiation (e.g., UV, visible, infrared) from penetrating the housing. Natural threats, such as animals and/or plant life may be prevented from entering the housing. In some instances, the housing may be fluid-tight. The housing may protect the components therein from impact (e.g., projectiles, blown objects). The housing may be formed from a rigid or semi-rigid material that may form a protective barrier from an external environment to the interior of the housing. The housing may or may not include a shock-absorbing material. The housing may optionally protect the components therein from fire.

Within the housing, there may be one or more security measures that may prevent theft, damage or tampering with the components within the housing. For instance, walls, compartments, cages, or other protective features may be provided within the housing, which may limit access to the components protected by the protective features. An individual may only be granted access if the individual identity if verified and/or the individual is authorized to access the component. In one example, one or more components may be protected by a protective compartment of the containerized unit. The compartment and/or the component may be within the housing. If an individual wishes to access the component, the user may be required to unlock the compartment, or perform any other action, as described elsewhere herein with respect to gaining access to the housing. The one or more protective features may be robust and resistant to damage, such as resistant to bullets, or other tools that may be used to try to gain access. In some instances, individuals may be granted access to the component within the protective feature by a remote user or terminal.

Security and Surveillance System

A containerized microgrid unit may employ one or more features, characteristics, or components that may aid in improving the security of the containerized microgrid unit. The containerized microgrid unit may be deployed to remote locations, so it may be useful to provide increased security for the components. The security features may reduce the likelihood of theft or vandalism to the components of the containerized microgrid unit. The security features may detect an error condition or malfunction with the containerized microgrid unit. The security features may also reduce the likelihood of damage from environmental conditions or inhabitants.

The housing may optionally prevent unauthorized individuals from entering the housing. For instance, the housing may require a key or a code for an individual to enter the housing. In some embodiments, an identity of an individual may be verified before an individual may enter the housing to access the components therein. The identity of the individual may be verified using a password, code, phrase, biometrics (e.g., fingerprint, handprint, voiceprint, retinal scan, image, thermal image, blood sample), or item carried by the individual (card, dongle, key, etc.). The individual may be allowed access to the interior of the housing if the individual is authorized to enter, and may alternatively be barred from entry if not authorized, or if their identity cannot be confirmed. In some instances, individuals may be granted access to the interior of the housing by a remote user or terminal.

A containerized microgrid system may include one or more sensors that may aid in security and surveillance. Examples of sensors may include image sensors, heat sensors, motion detectors, ultrasonic sensors, acoustic sensors, microphones, capacitive sensors, LIDAR, barometric sensors, trip wires, pressure plates, or any other type of sensor. The sensors may be used to detect the presence of an individual. The sensors may be used to identify the individual. The sensors may be used to detect the presence of an alarm event or condition. For example, a condition that may result in potential damage to the unit may be detected. For instance, if a fire breaks out near a component, the condition may be detected. If a percussive shock is delivered to the housing, the condition may be detected. The unit or one or more components are moved, or if components are removed from the housing or an acceptable perimeter, the condition may be detected.

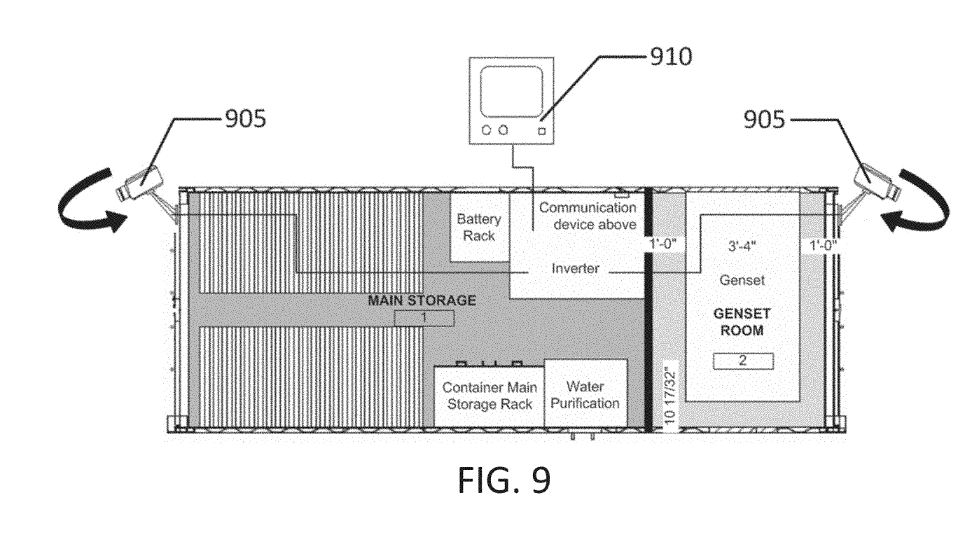

In some instances, the sensors may include video surveillance cameras. One or more surveillance cameras may be mounted from the top of the containerized unit. FIG. 9 depicts one possible embodiment of a surveillance system, wherein rotatable cameras 905 are mounted on the corners of the unit. Video footage from these cameras may be transmitted to an onsite video system or may instead be uploaded and transmitted to an offsite monitoring center 910 through the containerized microgrid communication system. The cameras may be equipped with sensors of greater than 3 megapixel, optical zoom, as well as pan and tilt functions. The may be connected to the communications system and equipped with remote access from smartphone, desktops, tablets or from a remote server or device. The cameras may be motion activated and begin capture of footage in response to motion triggers. In some embodiments the cameras may have a range may greater than 75 feet. The cameras may further be designed with infrared sensors or other mechanisms for collecting footage at night. The cameras may be weatherproof and designed to withstand exposure to severe conditions and exposure to the elements (e.g. heat, rain, sun, wind). The cameras may be designed to be difficult to steal, deface, damage or remove, for example they may be mounted from the inside of containerized microgrid housing. Cameras may be mounted at heights greater than 10 feet from the ground.

Any other mechanisms for locally or remotely monitoring and protecting the containerized microgrid or nearby solar panels may be employed. The containerized microgrid may be armed by a local user or remotely. If one or more of the sensors or surveillance systems activated the arming may trigger an alert. Alerts may include local alarms. The local alarms may produce an alert or warning, alerts or warning may comprise one or more loud noises, flashing lights, or shutting down of the generators or energy systems. The system may go into a lockdown state in response to sensor or surveillance system trigger, wherein the lockdown state provides higher security protection of the components within. Higher security protection may comprise additional panels, system locks or system shutdowns that are not easily reversed and may require external clearance before normal function can be restored. Activation of the alarm system may further comprise triggering of remote alarms wherein the signal may be transmitted from the communications system to offsite personnel or monitoring systems, alerting them of the system status and events. The alarm may be equipped to stream info live so offsite personal can monitor the events and conduct diagnostics to fix or repair the system or call for backup and support from users or others that can assist with restoring system function.

Loads and Power Distribution

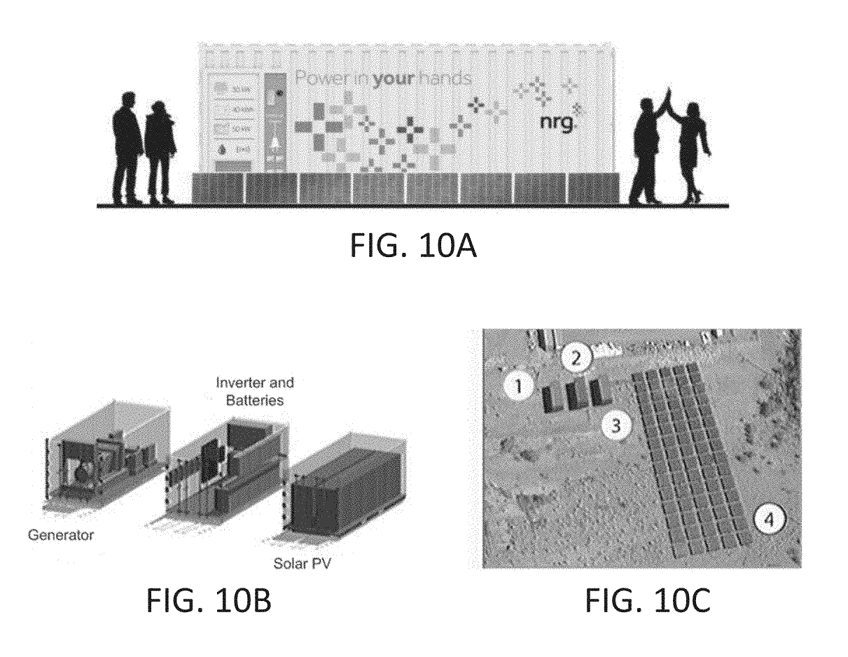

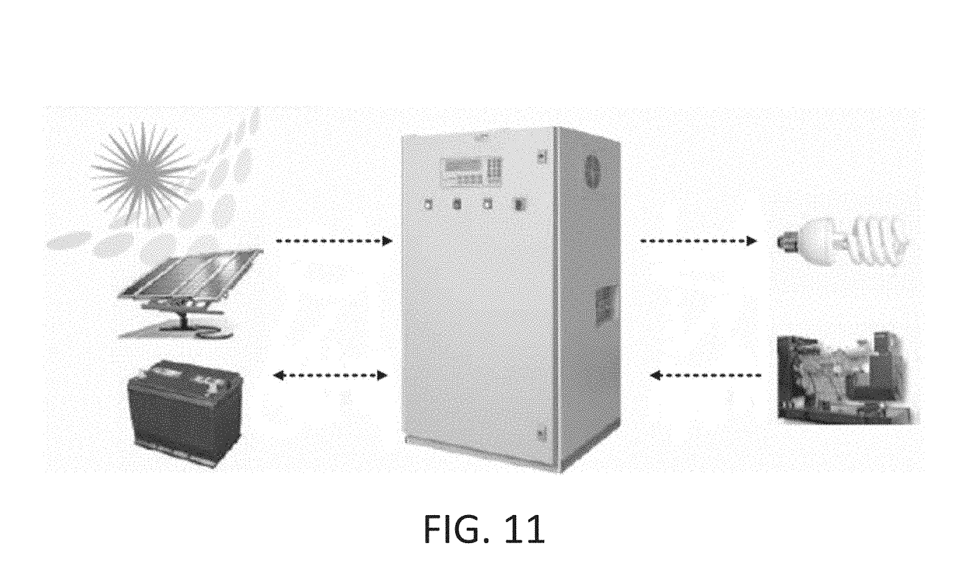

The units may be self-contained, as shown in FIG. 10A or linked together to meet higher demand or expanded needs of a system, as depicted in FIG. 10B-C. The containerized microgrid may comprise a solar array, battery bank and genset that support critical and non-critical loads. Critical loads may comprise a fan, PC-power & site controller, container lights, electric water pump, fuel pump, fire extinguishing system, AC unit for thermals, sensor surveillance and camera system and components of the communications system. The hybrid power control (HPC) control system, as showing in FIG. 11, can monitor the loads on the system and manage multiple energy sources; for example, sunlight may be absorbed by the surface of an array of photovoltaic solar cells inducing current that flows into the circuit from a solar array, depending on the loads of the system the HPC control system may facilitate some combination of storage of current flow from the solar panels as potential energy within the battery, direct usage of the current flow from the solar cells to support loads on the system, use of stored energy from the battery bank or activation of the genset for supporting the energy loads of the system. The HPC control system may be equipped with controls that regulate the distribution of power sources relative to the critical or non-critical nature of the loads and the system, and the loads of the system may include powering lights or other devices.

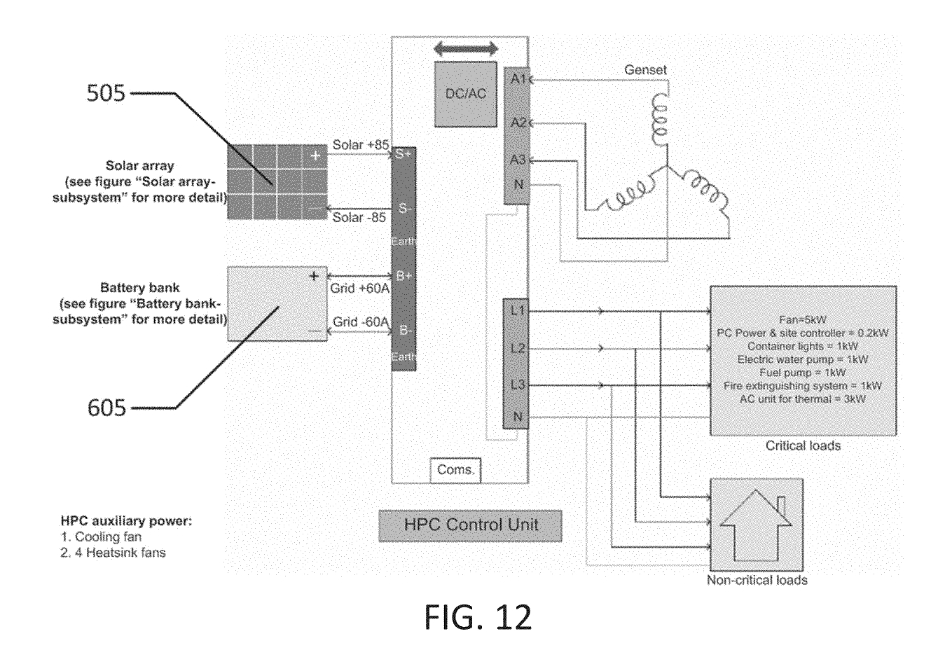

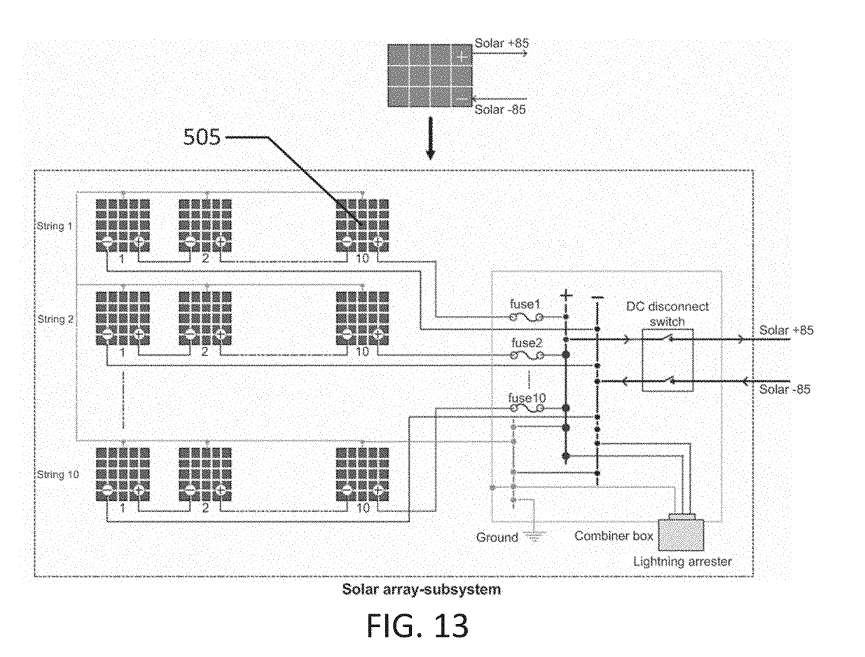

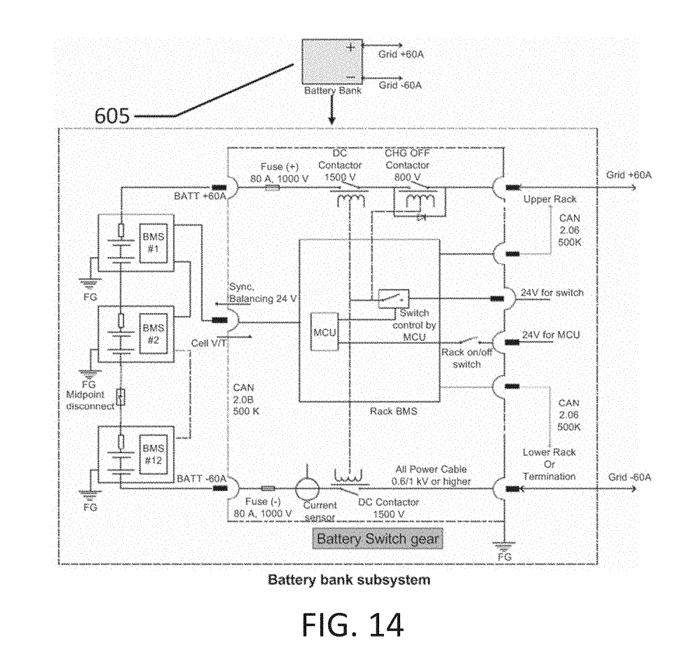

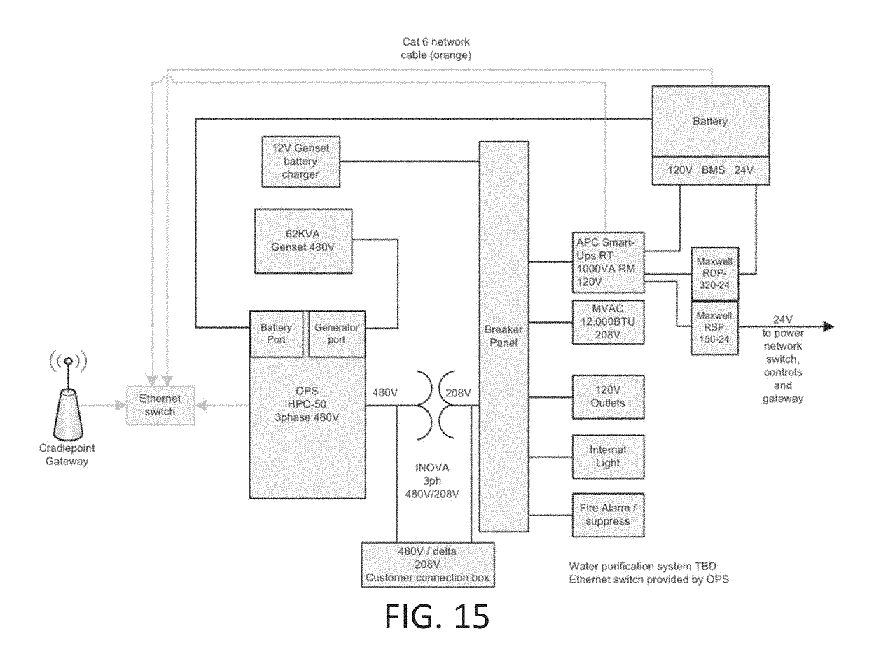

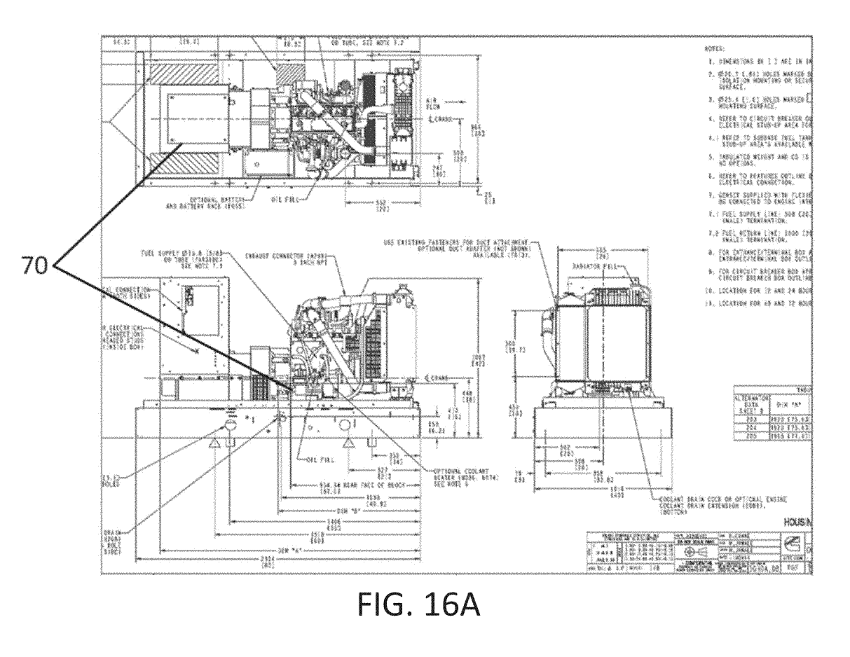

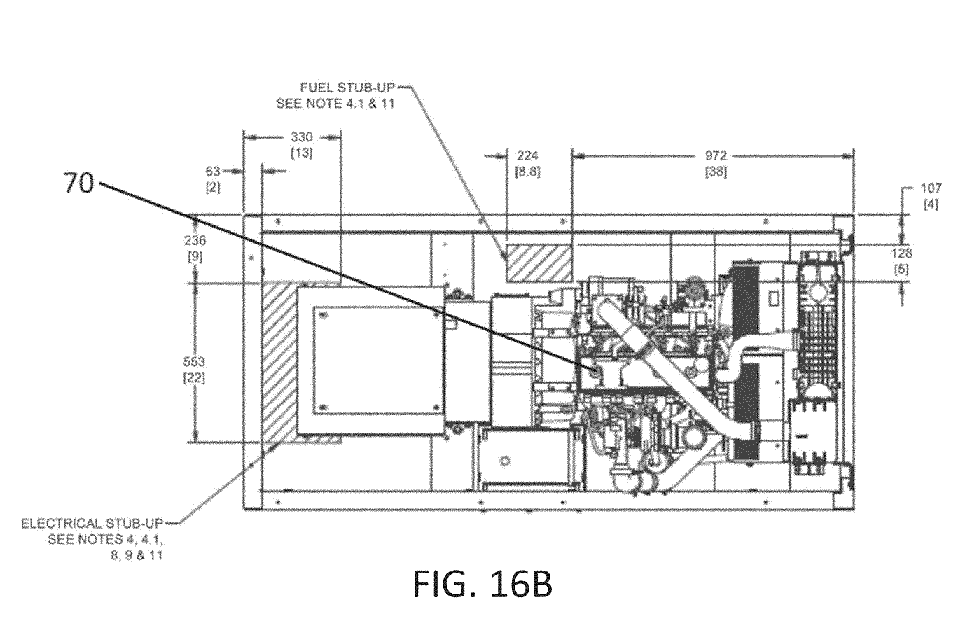

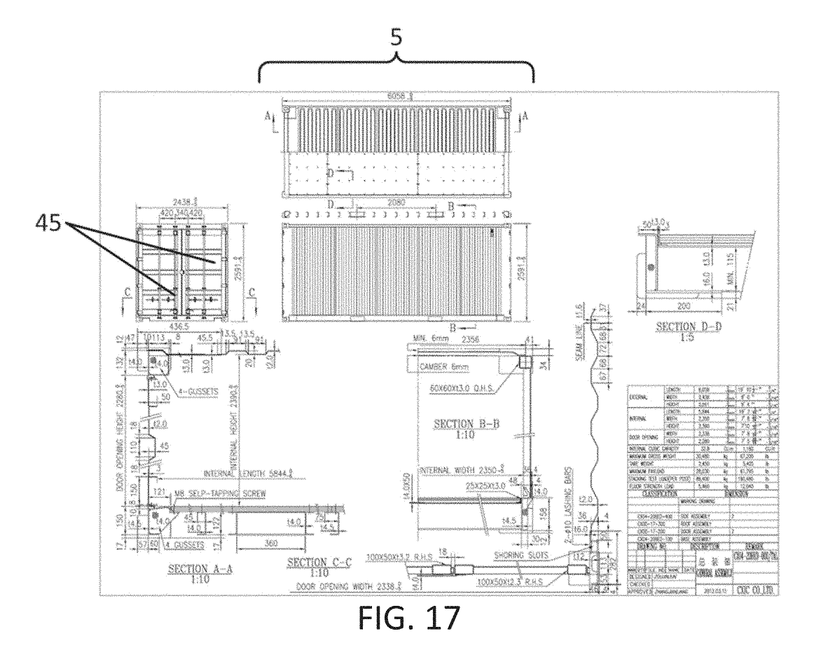

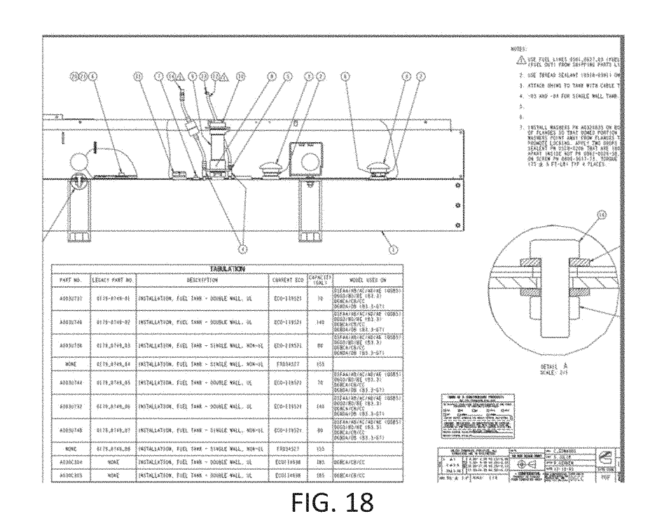

FIG. 12 is an example of a circuit diagram that may be used for some embodiments of the system. In some embodiments, for example, the containerized microgrid may comprise an inverter with a hybrid power conditioning unit for managing different energy sources including energy from a solar array (FIG. 13) and a battery bank (FIG. 14), and a genset. The inverter may also manage critical loads, and non-critical loads. The HPC unit may be configured to minimize fuel consumption from the diesel generator; it may further be configured to support critical loads over non-critical loads. Critical loads may comprise a fan, PC-power & site controller, container lights, electric water pump, fuel pump, fire extinguishing system, AC unit for thermals, sensor surveillance and camera system and components of the communications system. In some embodiments the solar array may be in installed in parallel circuit with the battery bank, and this parallel circuit may be in series with the genset and the HPC control unit. When the solar cells are active and producing current, the batteries may be charged and that stored energy may be available to the system. FIG. 15 depicts Cat6 ethernet wiring, as well as power sources for loads including internal lights, outlets, and the internet gateway, router and switch controls. FIG. 16 depicts schematics for a genset that may be used in some of the embodiments of the present applications.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

1. A containerized system comprising:
a transportable housing configured to enclose one or more components, wherein the one or more components include an inverter, a battery pack, a solar panel, or a fuel generator; and
one or more mounting systems within the housing, wherein the mounting systems are configured to support the one or more components,
wherein the mounting systems are not removable from the container and prevent tampering with at least one of the one or more components supported by the mounting systems.

2. The system of claim 1, further comprising a surveillance system configured to sense one or more conditions within the housing, and generate an alarm or alert when the one or more conditions match a predetermined alarm condition.

3. The system of claim 1, further comprising a communications system configured to permit a device within a proximity of the housing to communicate with a network.

4. The system of claim 3, wherein the communications system comprises a wireless internet access terminal.

5. A containerized system comprising:
a transportable housing configured to enclose or support one or more components, wherein the one or more components include an inverter, a battery pack, a solar panel, and a fuel generator; and
a surveillance system configured to sense one or more conditions within the housing, and generate an alarm or alert when the one or more conditions match a predetermined alarm condition indicative of tampering with at least one of the one or more components.

6. A method of providing a wireless hotspot, said method comprising:
delivering a containerized system comprising a housing configured to enclose or support an inverter, battery pack, solar panel, fuel generator, and a communication system, to a location;
providing power to the communication system, with aid of the battery pack, solar panel, or fuel generator; and
permitting a device within a proximity of the housing to communicate via a wireless network with aid of the communication system.

7. The containerized system of claim 1, further comprising a water purification system.

8. The containerized system of claim 1, wherein the mounting system forms a containerized unit around the one or more components that permits access to an individual after the individual's identity is verified and when the individual is authorized to access the one or more components.

9. The containerized system of claim 5, further comprising racks for mounting solar panels.

10. The containerized system of claim 5, wherein the surveillance system is powered by at least one of the one or more components enclosed or supported by the transportable housing.

11. The containerized system of claim 5, wherein the transportable housing includes a video recording system and a motion sensing alarm system.

12. The containerized system of claim 8, wherein the containerized unit is resistant to damage by tools or bullets.

13. The method of claim 6, further comprising transmitting a status of the containerized system to an external server.

14. The method of claim 17, wherein the status of the containerized system comprises a readout of the energy performance of one or more components within the containerized system.

15. The method of claim 6, wherein the wireless hotspot further comprises two or more routers, wherein one or more of the routers requires a connecting device to undergo an authentication protocol before gaining access to the internet and one or more of the routers does not require a connecting device to undergo an authentication protocol before gaining access to the internet.
